(19) United States
(12) Patent Application Publication
(10) Pub. No.: US 2025/0264917 A1
(43) Pub. Date: Aug. 21, 2025

(54) FLEXIBLE HINGE THERMAL ARCHITECTURE

(71) Applicant: Meta Platforms Technologies, LLC, Menlo Park, CA (US)

(72) Inventors: Ustun Duman, Palo Alto, CA (US); Kiarash Vakhshouri, Daly City, CA (US); Michael Nikkhoo, Saratoga, CA (US)

(21) Appl. No.: 18/140,937

(22) Filed: Apr. 28, 2023

Related U.S. Application Data
(60) Provisional application No. 63/437,918, filed on Jan. 9, 2023.

(51) Int. Cl. G06F 1/20; G02B 27/01; G06F 1/16; H05K 7/20

(52) U.S. Cl. CPC G06F 1/203; G02B 27/0176; G06F 1/163; G06F 1/1681; H05K 7/20327; G06F 2200/203

(57) ABSTRACT

A thermal system configured to bend in multiple directions and provide a thermal conduit to transfer heat through an electronic device having a bent or curved profile. A thermal system may include a first thermal management component, a second thermal management component, and a memory material coupler coupled to the first thermal management component and the second thermal management component. The memory material coupler is configured to provide mechanical articulation of the first thermal management component relative to the second thermal management component and transfer heat from a first location to a second location of the electronic device.

This application claims the benefit of and claims priority to U.S. Provisional Application No. 63/437,918, filed on Jan. 9, 2023, which is incorporated herein by reference.

### BACKGROUND

Recent advances in battery technology have enabled computationally powerful portable electronic devices. However, the batteries and electronics within these devices generate considerable amounts of heat. Many electronic devices include one or more hinges or bendable areas that make it difficult to adequately dissipate heat between various components. Existing thermal management systems are not well suited for dissipating heat between two or more components of an electronic device that are connected via a hinge, bendable area, or mechanical articulation.

### BRIEF DESCRIPTION OF THE DRAWINGS

The detailed description is described with reference to the accompanying figures. In the figures, the left-most digit(s) of a reference number identifies the figure in which the reference number first appears. The use of the same reference numbers in different figures indicates similar or identical components or features.

FIGS. 1A and 1B illustrate simplified schematic diagrams of example electronic devices having one or more thermal systems extending across a flexible or bendable region as described herein.

FIGS. 2A and 2B illustrate simplified schematic diagrams of example electronic devices having one or more thermal systems extending across a hinge or other bendable region as described herein.

FIGS. 3A-3C illustrate example thermal systems in which a memory material coupler is used to connect thermal management components of a thermal system.

FIG. 4 illustrates an example thermal system including a thermal management component including a flexible portion made from a memory metal cladding.

FIGS. 5A-5E illustrate example cross-sectional views of a thermal management component including a wick.

FIG. 6 illustrates an example electronic device usable to implement techniques such as those described herein.

### DETAILED DESCRIPTION

This application describes a bendable or flexible thermal system configured to spread heat through a flexible adapter hinge, bendable or flexible region, or mechanical articulation of an electronic device. In examples, the bendable thermal system may be configured to improve and/or provide mechanical stability to a hinge or other flexible region of an electronic device. In examples, the bendable thermal system may include a shape-memory alloy (SMA) or “memory material.” In examples, the bendable thermal system may include a metal or metal alloy. In examples, the bendable thermal system may include a memory metal. In examples, the bendable thermal system may include a nickel-titanium alloy (NiTi), for example Nitinol. In examples, the bendable thermal system may include a NiTi coupler or connector that is configured to connect two or more thermal management components (e.g., heat pipes, vapor chambers, glass tubes, heat spreaders, heat sinks, etc.). By way of example and not limitation, a NiTi coupler may be configured to couple a first thermal management component (e.g., heat pipe, vapor chamber, heat spreader, heat sink, etc.) to a second thermal management component (e.g., heat pipe, vapor chamber, heat spreader, heat sink, etc.). In some examples, additional memory metal couplers may be used to couple the first and/or second thermal management components to one or more additional thermal management components (e.g., heat pipes, vapor chambers, heat spreaders, heat sinks, etc.).

In examples, the bendable thermal system may include a NiTi cladding over a surface of a heat pipe located within a hinge. In examples, a thermal system may include a thermal management component that either includes or is connected to a flexible hinge structure cladded with NiTi. In examples, a thermal system may include a single, continuous thermal management component (e.g., a heat pipe) that is clad with a memory metal alloy (e.g., NiTi). In examples, a thermal system may include two or more thermal management components connected in series by one or more flexible hinge structures cladded with NiTi.

In examples, the bendable thermal system may be implemented to effectively and reliably transfer heat through a hinged or bendable portion of an electronic device. In some examples, the bendable thermal system may be configured to transmit heat between thermal management components such as heat pipes, vapor chambers, and/or glass tubes through the hinged or bendable portion. In examples, a thermal system may be a flexible thermal system which includes a flexible adapter hinge. The flexible adapter hinge may be used in an electronic device that may include a curved or bent portion, such as an angled side or element. In examples, an electronic device may include a coupler (e.g., a memory material coupler) configured to provide a mechanical articulation such as a hinge, fold, pivot pins, or other bendable, flexible, swinging, or rotatable structures. In examples, the thermal system may include two or more fluidly connected thermal management components, non-fluidly connected thermal management components, or a combination of both. In examples, the thermal management components may include a first glass tube and a second glass tube connected via a memory material coupler. In examples, the thermal management components may include a first vapor chamber and a second vapor chamber connected via a memory material coupler.

In examples, a bendable thermal system may include a flexible adapter hinge that includes an elongated member such as a solid connector, a hollow connector or coupler, a bellows, or any combination thereof. In examples, the flexible adapter hinge may include a memory material cladding (e.g., a layer or sleeve of NiTi or other memory material encircling or otherwise disposed on at least a portion of a surface of the bendable thermal system). In examples, a flexible adapter hinge of the thermal system may be provided at an adiabatic region of a thermal management component and/or of the thermal system.

In examples, a bendable thermal system may include one or wick(s) comprising a mesh structure, one or more fibers, or any combination thereof. The wick structures may be porous and may comprise a substantially planar sheet, a stack of multiple sheets, a substantially tubular or circular structure, a spiral structure, a braided structure, two or more twisted fibers, or the like. In examples, a bendable thermal system as described herein may include one or more wicks extending through at least a portion of a length of the internal volume (or center) of a memory material coupler to promote capillary action. In examples, a wick may be limited to extend across only the length of the memory material coupler. In examples, a wick may extend beyond the memory material coupler. In examples, a wick may extend through at least one thermal management component and/or at least to the condenser side of a thermal management component in addition to the memory material coupler. In examples, the wick may extend along the full internal length of the thermal system (e.g., the wick may extend from a first thermal management component, through the memory material coupler, and into a second thermal management component). In examples, a first set of wicks within an evaporator side of a first thermal management component (e.g., within a first vapor chamber, first heat pipe, first glass pipe, etc.) may overlap or partially interweave with a second set of wicks within a condenser side of a second thermal management component (e.g., within a second vapor chamber, second heat pipe, second glass pipe, etc.). In examples, a wick may extend through two or more thermal management components and one or more flexible adapter hinges or memory material couplers.

In examples, a thermal system may include a flexible adapter hinge that includes a thermally conductive material with NiTi cladding. In examples, the flexible adapter hinge may include a material that has a thermal conductivity of 100-200 W/mK or higher. In examples, the flexible adapter hinge may include a heat pipe containing a metal such as copper, aluminum, steel, titanium, nickel, etc. In examples, the flexible adapter hinge may include a heat pipe containing a polymer such as polysulfone, polyether-sulfone, polyamideimide (PAI), polyetherimide (PEI), polyetheretherketone (PEEK), polyphenylene sulfide (PPS), Nylon, with or without fiber reinforcement), polyurethane, polypropylene, polyimide, polyethylene terephthalate (PET), or composites such as carbon fiber, fiberglass, glass or any combination thereof.

In examples, an electronic device may be configured to include a thermal system as described herein. In examples, the thermal system may be configured to spread heat through and/or across different portions of the electronic device. In examples, spreading heat across different portions of the electronic device can enhance the dissipation of heat from the electronic device to the environment. In examples, spreading heat across different portions of the electronic device may include transferring heat from a first region of the electronic device to a second region of the electronic device. In examples, spreading heat across different portions of the electronic device may preempt overheating at one location of the electronic device. In examples, the thermal system may cause the electronic device to achieve or advance toward an isothermal condition.

In examples, a thermal management component (e.g., a heat pipe, vapor chamber, glass tube, etc.) may be configured to hold a working fluid (e.g., water, ionized water, glycol/water solutions, alcohol, acetone, dielectric coolants, etc.) that may be used to actively remove heat from components thermally coupled to the thermal management component. In examples, the thermal management component may be made of a flexible material. In examples, a thermal management component may have an outer diameter or outer width in the range of about 350 microns up to 3 mm. In some examples, the thermal management component may have an inner diameter or inner width in the range of about 150 microns to 2.8 mm, while in other examples the thermal management component may have larger inner diameters. In examples, the thermal management component may have a wall thickness of at least 100 microns. In one example, a thermal management component may include a glass internal body covered with an outer layer (e.g., a metal layer such as titanium, copper, polyimide or any combination thereof) over all or a portion of the internal body. In examples, a thermal management component may be larger or smaller than the ranges listed and/or can be made by additional or alternative manufacturing techniques.

In some examples, the working fluid may be circulated through a thermal management component via capillary action and thermal differentials throughout the thermal system. In some examples, the working fluid may be actively pumped throughout the thermal management component to increase the rate at which the working fluid circulates. In some examples, a thermal management component may additionally or alternatively include and/or be coupled to one or more other thermal management features (e.g., heatsinks, fins, radiators, fans, compressors, etc.) which may further increase the ability of the thermal management component to remove heat from components of the electronic device.

In examples, an electronic device may include a first elongated portion (e.g., a first glass tube, a first vapor chamber, a first heat pipe, etc.), a second elongated portion (e.g., a second glass tube, a second vapor chamber, a second heat pipe, etc.), and a memory material coupler (e.g., NiTi coupler) interposed between the first elongated portion and the second elongated portion. The memory material coupler may be attached to the first elongated portion and the second elongated portion in a manner that creates a compression seal or hermetic seal between the first elongated portion and the second elongated portion. The memory material coupler may be configured to provide mechanical articulation of the second elongated portion relative to the first elongated portion. A thermal system may extend from the first elongated portion to the second elongated portion and may be configured to extend across or through the memory material coupler.

While the examples described above discuss heat pipes, vapor chambers, or other thermal management components constructed of a substantially rigid material, such as glass, metal (e.g., copper), or the like, which are coupled together via a coupler made of a memory metal material, in some examples, the heat pipes, vapor chambers, or other thermal management components may themselves be constructed of a memory metal material, such as NiTi. Additionally or alternatively, while examples are shown and described in which multiple heat pipes are coupled together via one or more memory metal couplers, and embodiments are shown and described in which multiple vapor chambers are coupled together via one or more memory metal couplers, other configurations and permutations are also envisioned. For example, one or multiple heat pipes may be coupled to a vapor chamber via one or multiple memory metal couplers. Additionally or alternatively, any of the heat pipes, vapor chambers, heat spreaders, or other thermal management components described herein may be coupled to any other heat pipes, vapor chambers, heat spreaders, or other thermal management components via one or more memory metal couplers. By way of example and not limitation, one example of a heat spreader includes a rod, sheet, block, or other form factor made of graphite (e.g., solid graphite, pyrolytic graphite, a substrate or resin mixed or impregnated with graphite particles, etc.).

These and other aspects are described further below with reference to the accompanying drawings. The drawings are merely example implementations and should not be construed to limit the scope of the claims. For example, while examples are illustrated in the context of a head-mounted electronic device, the techniques may be used in association with any electronic device.

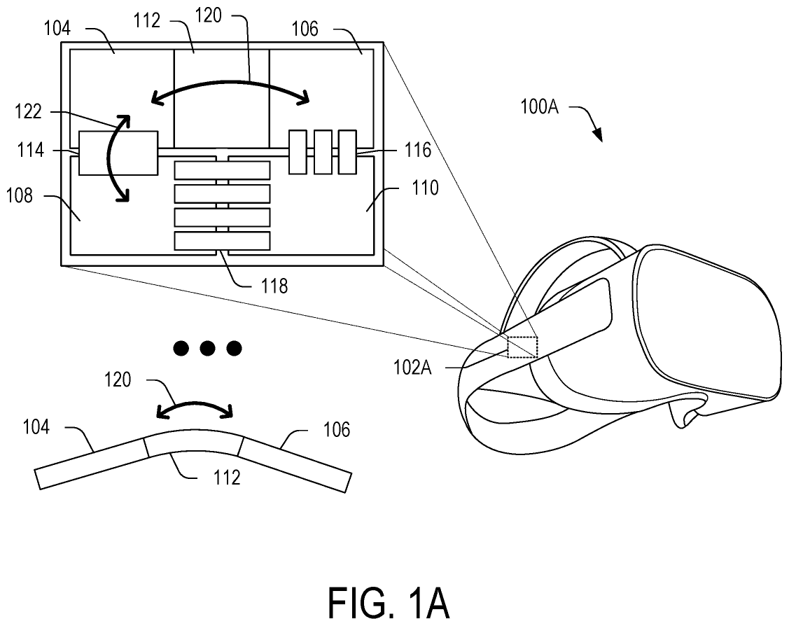

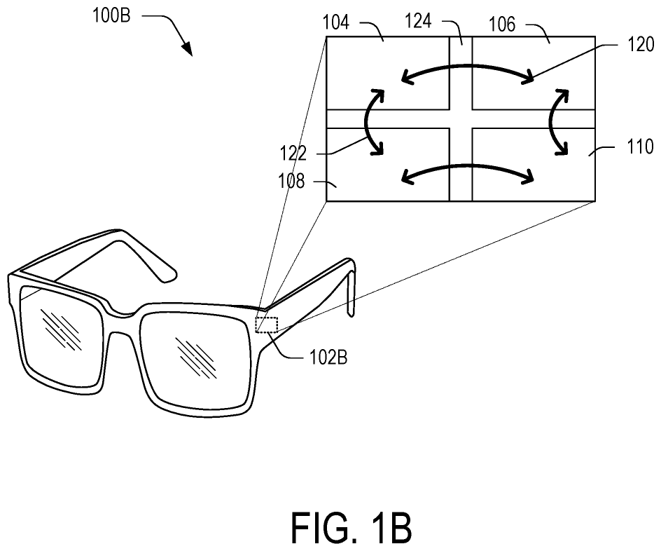

FIGS. 1A and 1B illustrate simplified schematic diagrams of example electronic devices having one or more thermal systems extending across a flexible or bendable region as described herein.

FIG. 1A illustrates an example electronic device 100A in the form of a headset device including a curved and/or bendable region 102A. In examples, the headset device may be made of a flexible material (e.g., including a woven or non-woven fabric, a natural or synthetic fiber fabric, silicone-based textile, and/or other flexible materials) and may be configured to interact with a user's sense of touch by applying mechanical forces, vibrations, and/or motions. The haptic feedback device may include electronic components throughout the device that generate heat (e.g., processor, printed circuit board, integrated circuit, etc.) and a bendable thermal system to help transfer heat away from these heat producing components and/or to an environment.

The curved and/or bendable region 102A may be located in any portion of the headset device (e.g., housing, strap, head-engaging portions, etc.). The curved and/or bendable region 102A may include two or more rigid or semi-rigid thermal management components (e.g., thermal management component(s) 104, 106, 108, 110) that are joined together via one or more flexible memory material couplers (e.g., memory material coupler 112, 114, 116, 118). In examples, thermal management component(s) 104, 106, 108, 110 may comprise a vapor chamber constructed of a rigid material such as glass or metal (e.g., copper, etc.) or a combination of rigid materials, and joined (e.g., welded, brazed, adhered, press fit, clamped, fastened, etc.) together using a flexible memory material (e.g., NiTi). FIG. 1A includes a first arrow 120 and second arrow 122 that illustrate how the thermal system is configured to bend or flex in one or multiple directions (about multiple different bending axes). Though FIG. 1A only depicts four thermal management components, any number of thermal management components may be coupled via any number of memory material couplers. For example, a perimeter of thermal management component 104 may be coupled to one or more additional thermal management components not shown in FIG. 1A.

In examples, memory material coupler 112 may extend around an entire perimeter of a thermal management component (e.g., around a perimeter of an interface between thermal management component 104 and thermal management component 106 coupled via memory material coupler 112) or may couple one or more portions of thermal management components (e.g., thermal management component 104 is coupled to thermal management component 108 via memory material coupler 114, thermal management component 106 is coupled to thermal management component 110 via memory material couplers 116, and thermal management component 108 is coupled to thermal management component 110 via memory material couplers 118). As shown in FIG. 1A, any number of memory material couplers of various shapes and sizes may be utilized to couple two or more thermal management components. In some examples, such as the case of memory metal coupler 112, memory metal couplers may be hollow and hermetically seal to and provide a common, continuous vapor space with the vapor chambers to which the memory metal coupler attaches. In other examples, the memory metal couplers may be solid and/or may not constitute part of the vapor space of the adjacent vapor chambers.

FIG. 1B illustrates an example electronic device 100B in the form of a pair of extended reality glasses having a curved and/or bendable region 102B. The bendable region 102B may include a thermal system and be located on any portion of the extended reality glasses that is curved, flexes, bends, and/or twists in one or multiple directions. In examples, the thermal system may include two or more rigid or semirigid portions (e.g., thermal management components 104, 106, 108, 110) joined together by a single memory material coupler 124 that is joined (e.g., welded, brazed, adhered, press fit, clamped, fastened, etc.) or otherwise configured to couple the two or more rigid portions. Memory material coupler 124 enables the thermal system to bend in multiple directions as illustrated by a first arrow 120 and second arrow 122 while minimizing stresses or forces from being applied to the more rigid thermal management components 104, 106, 108, 110.

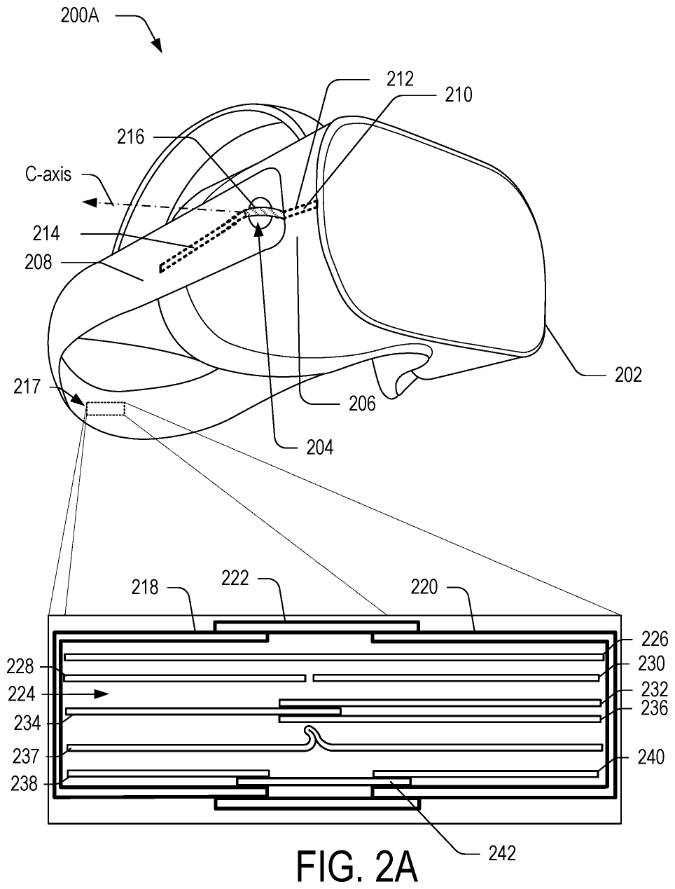

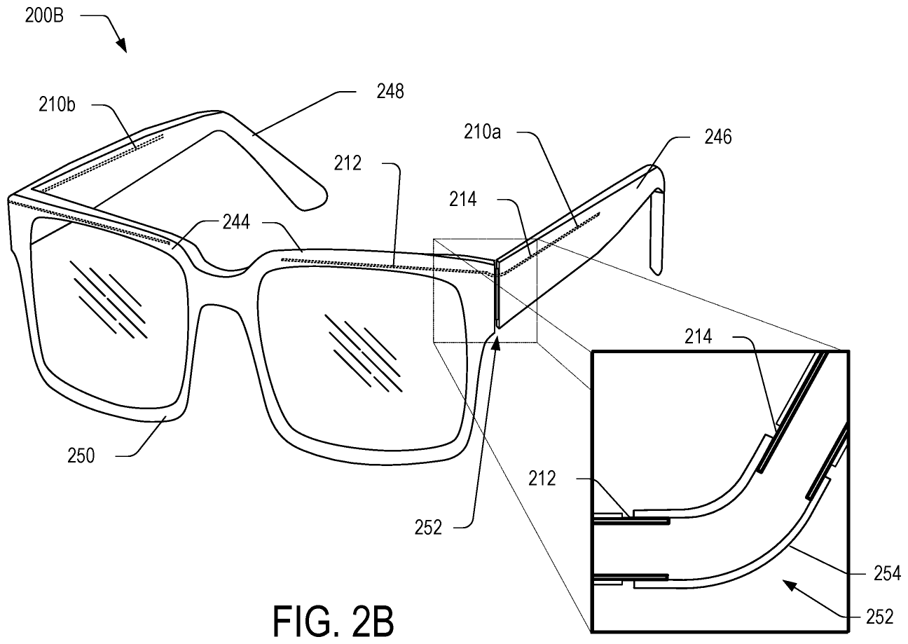

FIGS. 2A and 2B schematically illustrate examples of electronic devices that may be equipped with a thermal system as described herein. In examples, the electronic device may include a head mounted device as shown in FIGS. 2A and 2B in which a first elongated and/or planar portion may include a frame of the head-mounted device and a second elongated and/or planar portion may include a strap or temple arm of the head mounted device.

FIG. 2A illustrates an electronic device 200A in the form of an extended reality headset 202 that may include an articulated portion or flexible region (e.g., within a strap). In examples, the extended reality headset 202 may include a first portion 206 and a second portion 208. In examples, first portion 206 may be a frame portion of the extended reality headset 202. In examples, second portion 208 may be a side or temple arm of extended reality headset 202, such as for example a strap. In examples, an articulation region 204 may be provided between the first portion 206 and the second portion 208 and configured to provide a mechanical articulation between the first portion 206 and the second portion 208. In examples, the articulation region 204 may allow for a pivoting motion of second portion 208 about a central axis (C-axis) perpendicular to the first portion 206. In some examples, the articulation region 204 may include a coupler, such as a memory material coupler 216 that is configured to couple a first thermal system portion 212 (e.g., a first glass tube) and a second thermal system portion 214 (e.g., a second glass tube).

As shown, in examples, a thermal system 210 may be arranged so that a first thermal system portion 212 may be provided in first portion 206 and a second thermal system portion 214 may be provided in second portion 208. In examples, any number of thermal systems may be provided within the electronic device 200A (e.g., within first portion 206, second portion 208, articulation region 204, flexible region 217, etc.).

In examples, the first thermal system portion 212 of thermal system 210 may include a first thermal management component (e.g., vapor chamber, glass tube or a first portion of a glass tube, heat pipe, etc.). In examples, the second thermal system portion 214 of thermal system 210 may include a second thermal management component (e.g., a vapor chamber, glass tube or a second portion of a glass tube, heat pipe, etc.). In examples, the first thermal system portion 212 may be coupled to the second thermal system portion 214 via a coupler, an integrated bellows, a connected bellows, a hollow connector, or a solid connector. In examples, a memory material coupler 216 may be disposed within the articulation region 204 (or hinge) and interposed between a mating end of the first thermal management component and a mating end of the second thermal management component. The memory material coupler 216 may be configured to provide a mechanical articulation of the first thermal management component relative to the second thermal management component. In examples, the memory material coupler 216 of thermal system 210 may be configured to bend and/or flex in one or more directions to accommodate the pivoting articulation provided within articulation region 204.

In examples, thermal system 210 may include additional thermal management components that may be serially arranged in electronic device 200A. For example, in extended reality headset 202, additional thermal management components may be provided proximate the first thermal system portion 212 and/or second thermal system portion 214.

Electronic device 200A may include any number of articulation regions, flexible adapter hinges, memory material couplers, vapor chambers, heat pipes, and/or glass tubes. In examples, a strap of the electronic device 200A may include a flexible region 217 including a first thermal management component 218 (e.g., a first vapor chamber, a first glass tube, first heat pipe, etc.) and a second thermal management component 220 (a second vapor chamber, a second glass tube, second heat pipe, etc.). In examples, the first thermal management component 218 may be comprised of a first material (e.g., metal, glass, or the like) or a combination of materials and the second thermal management component 220 may be comprised of a second material different than the first material, or a combination of materials different than the first material. The first thermal management component 218 and the second thermal management component 220 may be joined via memory material coupler 222. In some examples, a first memory material coupler may couple an outer portion of a first thermal management component 218 to an outer portion of a second thermal management component 220 and a second memory material coupler may couple an interior portion of the first thermal management component 218 to an interior portion of a second thermal management component 220. In examples, the first thermal management component 218 may be a first vapor chamber comprising an evaporator portion and the second thermal management component 220 may be a second vapor chamber comprising a condenser portion and one or more wicks may be utilized to transfer fluid from the condenser side to the evaporator side of the thermal system.

In examples, the first thermal management component 218 and the second thermal management component 220 may include any number of wicks positioned within vapor space 224. In some examples, a continuous wick 226 may extend across an interior of the first thermal management component 218, through the memory material coupler 222, and the second thermal management component 220. In some examples, one or more wicks may partially extend across a vapor space 224 (e.g., wick 228 and wick 230). For example, wick 228 may partially extend through the first thermal management component 218 and/or through the memory material coupler 222 and wick 230 may partially extend through the second thermal management component 220 and/or through the memory material coupler 222. In some examples, two or more wicks may partially extend through a flexible region 217 (e.g., through memory material coupler 222) and overlap or interweave in order to resist fatigue or damage from repeated bending of the memory material coupler 222. For example, wick 234 may be positioned between wick 232 and wick 236. In some examples, a wick 237 may be formed with a loop of slack material to act as a strain relief to accommodate bending of the heat pipe or vapor chamber. In some examples, two or more wicks may be joined together via one or more wick memory material coupler(s) 242. For example, wick 238 is coupled to wick 240 via a wick memory material coupler 242. In some examples, a first side of the wick memory material coupler 242 may couple a first wick and a second wick and a second side of the wick memory material coupler 242 opposite the first side may be coupled to an inner surface (i.e., the surface facing the vapor space 224) of a first thermal management component and an inner surface of a second thermal management component.

In examples, a wick may include a mesh (e.g., copper mesh), one or more fibers, or any combination thereof. In examples, a first wick (or a first wick structure) of a first type may be joined to a second wick (or second wick structure) of a second type. For example, a first wick structure may comprise a mesh including copper wire of a first diameter and a second wick structure may comprise a mesh including copper wire of a second diameter different than the first diameter. In examples, a first wick structure may be designed with openings of a first size (e.g., a fine copper or other mesh having openings ranging from about 0.03 mm to about 0.122 mm) and a second wick structure may be designed with openings of a second size (e.g., a coarse copper or other mesh having openings ranging from about 1.35 mm to about 2.8 mm). In some examples, the first wick structure and the second wick structure may be joined to form a mesh junction. In some examples, the first wick structure and the second wick structure may be coupled using one or more memory material couplers. In at least one example, a bottom layer or floor of the vapor space may include a first wick structure and a second wick structure bonded together with one or more memory material couplers. In some examples, two or more wick structures may be stacked on top of one another in order to accommodate various power levels. In examples, a density or size of the copper mesh may be tailored in order to adjust capillary action or flow of liquid between an evaporator side and condenser side of a thermal system.

FIG. 2B illustrates another version of an electronic device 200B in which one or more thermal systems 210 (e.g., 210a and 210b) may be employed. Shown in FIG. 2B is an electronic device 200B with a hinge 252 (e.g., a flexible adapter hinge) including a memory material coupler 254. In examples, the electronic device 200B may be a type of extended reality glasses 250. In examples, a thermal system 210a may be arranged in extended reality glasses 250 such that a first thermal system portion 212 (e.g., a first glass tube, a first vapor chamber, etc.) of the thermal system 210a may be provided at a first elongated and/or planar portion 244 (e.g., a frame or portion of a frame) of the extended reality glasses 250, and a second thermal system portion 214 (e.g., a second glass tube, a second vapor chamber, etc.) of the thermal system 210a may be provided at a second elongated and/or planar portion 246 (e.g., a temple or portion of a temple) of the extended reality glasses 250. A hinge 252 or mechanical articulation may be provided between the first thermal system portion 212 and the second thermal system portion 214. The first thermal system portion 212 and the second thermal system portion 214 may be coupled or connected via a memory material coupler 254 located within the hinge 252 of the extended reality glasses 250. In examples, the memory material coupler 254 may be configured to mechanically articulate the pivoting, swinging, and/or rotation of the first elongated and/or planar portion 244 with respect to the second elongated and/or planar portion 246.

In examples, the memory material coupler 254 may be positioned within a hinge (e.g., hinge 252), curved area, or articulation region so that substantially all of the bending occurs at the memory material coupler 254 and not at the first thermal system portion 212 (e.g., a first glass tube, a first vapor chamber, etc.) or the second thermal system portion 214 (e.g., a second glass tube, a second vapor chamber, etc.). In examples, the memory material coupler 254 may be coupled at least partially to a housing of an electronic device 200B. In examples, the first thermal system portion 212 may be at least partially coupled to a frame of the extended reality glasses 250 and the second thermal system portion 214 may be at least partially coupled to a temple of the extended reality glasses 250 in order to minimize stresses imparted on the first thermal system portion 212 and the second thermal system portion 214.

Although as illustrated in FIG. 2A and 2B an electronic device includes a thermal system 210 extending across a mechanical articulation area, flexible region, or hinge, in examples, two or more thermal systems 210 may be connected to each other. For example, thermal systems 210a and 210b, where a thermal system 210a extends from the first elongated and/or planar portion 244 to the second elongated and/or planar portion 246 of electronic device 200B and thermal system 210b extends from the first elongated and/or planar portion 244 to a third elongated and/or planar portion 248 of electronic device 200B and may be operatively connected to each other. In examples, second elongated and/or planar portion 246 and third second elongated and/or planar portion 248 may be opposite each other, such as for example, the temple arms or side or temple portions of an extended reality glasses 250 as illustrated in FIG. 2B. In examples, two thermal systems 210a and 210b may be operatively, directly, and/or physically connected at first elongated and/or planar portion 244. In examples, a connecting element such as a memory material coupler 254 (e.g., a NiTi coupler) as described here may form the connection between the two thermal systems. In examples, a first glass tube or a first vapor chamber may extend across the first elongated and/or planar portion 244 and be connected via a memory material coupler 254 to a second glass tube or a second vapor chamber located within the second elongated and/or planar portion 246.

In examples, although not illustrated, electronic device 200B may be any other type of electronic device as previously described. In examples, an electronic device may include both a static curved section and a mechanical articulation or hinge. A thermal system may be arranged within such electronic device having both a static curved section and a mechanical articulation or hinge in the same manner as described.

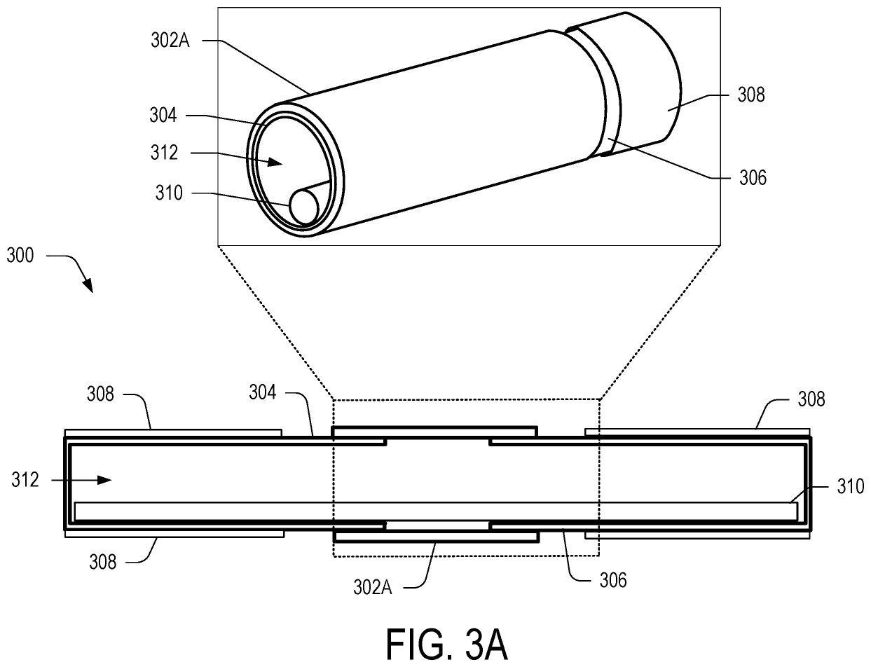

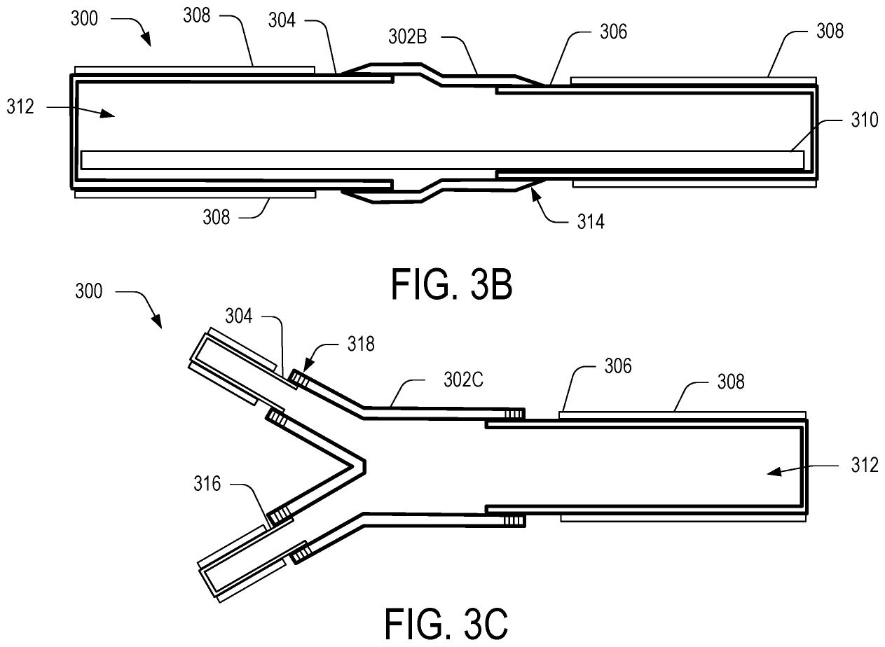

FIGS. 3A-3B illustrate example thermal systems in which a memory material coupler is used to connect thermal management components (e.g., glass tubes, vapor chambers, etc.) of a thermal system 300. FIG. 3A illustrates an example thermal system 300 in which a memory material coupler 302A is used to connect a first glass tube 304 and a second glass tube 306. In examples, the memory material coupler 302A may be disposed within a hinge or articulation region of an electronic device. The memory material coupler 302A may be coupled to one or more types of thermal management components. For example, the memory material coupler 302A may be coupled to a first glass tube 304 and a second glass tube 306 such that the memory material coupler 302A provides mechanical articulation of the first glass tube 304 relative to the second glass tube 306.

In examples, the memory material coupler 302A may comprise a shape memory alloy. In examples, a shape memory alloy may include NiTi. In examples, NiTi may include at least 50% nickel. In examples, NiTi may include 50% nickel or 51% nickel. In examples, the NiTi is binary NiTi where the balance of the alloy is titanium. In examples, the NiTi may be a ternary system where the balance may be substantially titanium, however, some small amounts or traces of other materials may be present as well, for example Pt, Hf, Cu, etc.

In examples, a memory material coupler 302A may be formed at a temperature that is below a deformation temperature of the memory material. In examples, a memory material coupler 302A may be formed by casting the nickel-titanium alloy, then hot drawing the nickel-titanium alloy at a temperature ranging from about 800° C. to about 1000° C. In examples, the metal may then be followed by cold drawing with inter-annealing conducted at a temperature of about 500° C. to about 600° C. until a final desired form is obtained. In examples, the formed memory material coupler 302A may be annealed at temperature between about 300° C. and 550° C.

In examples, the formed memory material coupler 302A may be configured to bend and return to its original shape when heated. Also, in examples, after the memory material coupler 302A is formed, it may be heated to a temperature above the deformation temperature and then cooled to returned to the initially formed shape. In examples, a memory material coupler 302A may be formed as a hollow connector having two mating ends. In examples, the mating ends may be configured to mate with respective thermal management components that the memory material coupler 302A is configured to connect. For example, the memory material coupler 302A may be configured to connect to a mating end of a first glass tube 304 and a mating end of a second glass tube 306.

In examples, memory material coupler 302A may include any desired cross-sectional shape. In examples, a memory material coupler 302A may include a cylindrical, trilateral, quadrilateral, polygonal, or curved shape. In examples, a memory material coupler 302A may include a round cross-sectional shape. In examples, a memory material coupler 302A may include a cross-sectional shape that matches the cross-sectional shape of the one or more thermal management components with which it is configured to mate.

In examples, a first glass tube 304 and second glass tube 306 may have similar or different structures. In examples, the first glass tube 304 and the second glass tube 306 may be made from an alumina silicate and/or borosilicate glass. In examples, the glass may be semi-flexible and able to achieve a bend radius of 20 mm to 30 mm. In examples, the first glass tube 304 and the second glass tube 306 may have any desired cross-sectional shape. In examples, a glass tube may have an outer diameter or outer width in the range of about 350 microns up to 3 mm. In examples, the glass tube may have an inner diameter or inner width in the range of about 150 microns to 2.8 mm. In examples, the glass tube may have a wall thickness of at least 100 microns.

In examples, the one or more glass tubes may include an outer coating 308. In examples, an outer coating 308 may include a thermally conductive material such as a metal or polymer. In examples, the outer coating 308 may include an electrically conductive material. In examples, the outer coating 308 may include polyimide.

In examples, a wick 310 and a vapor space 312 may be included in each of the first glass tube 304 and second glass tube 306. In examples, the wick 310 may be a single contiguous wick structure that extends from the first glass tube 304, through the memory material coupler 302A, and to the second glass tube 306. In examples each of the first glass tube 304 and the second glass tube 306 may include at least one mating end configured to engage a respective mating end (or receiving end) of the memory material coupler 302A.

In examples, a memory material coupler 302A may be connected to one end of the first glass tube 304 and to one end of the second glass tube 306. In examples, a memory material coupler 302A may include a first mating end and a second mating end. In examples, the first mating end and the second mating end may be opposite each other. In examples, the engagement between a mating end of a memory material coupler 302A and a mating end of a glass tube may be effectuated by mechanical boding. In examples, mechanical bonding may be effectuated, for example, by heating the memory material coupler 302A to a temperature above the deformation temperature of the memory metal material used to make the memory material coupler 302A so as to allow insertion of the rigid portions of the first and second glass tubes at the respective mating ends of the memory material coupler 302A. The memory material coupler 302A may then be cooled and/or allowed to cool. In examples, the memory material coupler 302A may include a memory material that, as it cools, may cause the memory material coupler 302A to transition to its pre-heated shape. In examples, the memory material coupler 302A can expand upon heating and returns to (or shrinks) to its pre-heated shape upon cooling. In examples, after the mating ends of the glass tubes are inserted into the open ends (or receiving ends) of the expanded memory material coupler 302A at the elevated temperature, the memory material coupler 302A may be cooled or allowed to cool to return to its original shape. In examples, as the memory material coupler 302A shrinks back to its original space, it may mate and form a seal, or hermetic connection with the first glass tube 304 and the second glass tube 306 that were inserted in the memory material coupler 302A. In examples, the memory material coupler 302A may create a compression fit or compression seal over the first glass tube 304 and the second glass tube 306. In examples, the memory material coupler 302A may have a smaller inner diameter relative to an outer diameter of a glass tube such that a hermetic seal is formed between the memory material coupler 302A and the glass tube.

In examples, the memory material coupler 302A may overlap an end of a glass tube by about 0.5 mm to about 2 mm. In examples, the memory material coupler 302A may overlap and end of a glass tube by about 1 mm. In examples, the outer coating of a glass tube may be configured to expose at least an end portion of the glass tube to avoid interference with the connection to the memory material coupler 302A. In examples, a gap may be formed between the outer coating 308 on the glass tube and the mating end of the memory material coupler 302A when connected to the glass tube. In examples, the gap between the outer coating 308 and the memory material coupler 302A may have a width of about 1 mm to about 2 mm. In examples, the memory material coupler 302A may be positioned between about 1 mm to 2 mm away from the polyimide coating extending over the portion of the first glass tube and between about 1 mm to 2 mm away from the polyimide coating extending over the portion of the second glass tube. The space or gap between the outer coating 308 (e.g., polyimide coating) and the memory material coupler 302A ensures that the hermetic seal is not broken between the memory material coupler 302A and the first and second glass tubes.

In examples, once bonded to the first glass tube 304 and second glass tube 306, the memory material coupler 302A may provide fluid communication between the first glass tube 304 and the second glass tube 306. In examples, the memory material coupler 302A may include a hollow internal volume, space, or center through which fluid may flow. In examples, the hollow internal volume or space may extend within the memory material coupler 302A from a first mating end of memory material coupler 302A to a second mating end of the memory material coupler 302A. In examples, the hollow internal volume or space may allow for working fluid and/or vapor to flow through.

In examples, a hollow internal volume or space of a memory material coupler 302A may be configured to house one or more wick(s) 310. In examples, a wick 310 of a first thermal management component (e.g., a first glass tube 304) and/or of a second thermal management component (e.g., a second glass tube 306) may be configured to extend at least into a portion of internal volume or space of the memory material coupler 302A. In examples, a contiguous wick 310 may be configured to extend from the first thermal management component to the second thermal management component passing through the internal volume or space of the memory material coupler 302A.

In examples, a contiguous wick 310 may be inserted inside the first glass tube 304, second glass tube 306, and a memory material coupler 302A during manufacturing after the memory material coupler 302A is coupled to the first glass tube 304 and the second glass tube 306. For example, the first glass tube 304 may be configured to have an open end, at an opposite side from the mating end with the memory material coupler 302A. After the memory material coupler 302A is bonded to the first glass tube 304 and the second glass tube 306, a wick mesh and/or fiber may be inserted through the open end of the first glass tube 304. In examples, a wick 310 may be provided in the memory material coupler 302A prior to bonding the memory material coupler 302A to the first glass tube 304 and the second glass tube 306. The open end of the first glass tube 304 may then be sealed and a vacuum created inside the first glass tube 304, second glass tube 306, and memory material coupler 302A. A working fluid may be inserted via an orifice provided, for example, at a sealed end of the first glass tube 304 or at an opposite end of the thermal system 300. In examples, an open end may be provided in the second glass tube 306 instead of the first glass tube 304. In examples, an open end may be provided at both the first glass tube 304 and the second glass tube 306, in which case both open ends would then be sealed prior forming a vacuum inside the bonded structure.

In examples, a wick 310 may enhance capillary action to transfer a fluid from a first side of a thermal management component (e.g., a first side of the first glass tube 304) to a second side of the thermal management component (e.g., a second side of the first glass tube 304) and/or from a first thermal management component (e.g., a first glass tube 304) to a second thermal management component (e.g., a second glass tube 306). In examples, a wick 310 may have a water surface energy such that it exhibits hydrophilicity at an evaporation side of a thermal management component and hydrophobicity at a condensation side of the thermal management component. In examples, the surface energy and thus exhibited hydrophilicity characteristics of a wick 310 may gradually vary from a first end of an adiabatic region to a second end, opposite the first end, of the adiabatic region. In examples, the hydrophilicity of a wick 310 may be higher at one end of the adiabatic region than at the opposite end of the adiabatic region. In examples, the surface energy of a wick 310 at a portion of the adiabatic region adjacent an evaporation side of a thermal management component may be similar or close to the surface energy of the wick 310 at the evaporation side of the thermal management component, while the surface energy of a wick 310 at an portion of the adiabatic region adjacent a condensation side of a thermal management component may be similar or close to the surface energy of the wick 310 at the condensation side of the thermal management component. In examples, the surface energy of a wick 310 may be affected by surface treatment such as oxidation or silane treatment. In examples, a wick 310 may extend at least along an internal portion of a thermal management component (e.g., an internal portion of the first glass tube 304). In examples, a wick 310 may extend the full or almost the full internal length of thermal management component. In examples, a wick 310 may include a mesh, fiber, a corrugated surface, or any combination thereof.

In examples, a wick 310 (e.g., a mesh wick) may include a metal (e.g., copper), carbon, polymer, or any combination thereof. In examples, a wick 310 may include a metal such as copper, copper alloy, titanium, titanium alloy, aluminum, aluminum alloy, or any combination thereof. In examples, a wick 310 may be sintered or unsintered. In examples, a wick 310 may include a composite structure. In examples, a wick 310 may include woven wires such as a mesh, metal foams, sintered powders, one or more coatings, or any combinations thereof. In examples, a coating may be Al₂O₃/SiO₂ bilayer. In examples, a wick 310 may include copper or copper alloy, nylon, or any combination thereof. In examples, a wick 310 may be bonded to an internal surface of a glass tube. In examples, a wick 310 may be bonded to an internal surface of a heat pipe (e.g., a glass tube) by spot welding, brazing, clamping, thermal compression, thermosonically, or like process.

In examples, a wick 310 may include a material that has a water contact angle of less than 45°. In examples, a wick 310 may include a material that has a contact angle of less than 40°, less than 35°, less than 30°, less than 25°, less than 20°, less than 15°, and at least 5°. In examples, a wick 310 may include fibers having a diameter ranging from about 20 μm to about 80 μm. In examples, a wick 310 may include fibers having a diameter in the range of about 25 μm to 75 μm.

In examples, a wick 310 may be a fiber wick and may include a treated polymer material, a metal, and/or glass. In examples, a wick 310 may include polyethylene terephthalate (PET). Other polymers may also be used. In examples, a wick 310 may include glass fiber or a metal fiber. In examples, a wick 310 may include a functionalized material, for example a functionalized polymer and/or functionalized metal. In examples, functionalization of a polymer fiber may be effectuated via a plasma process. In examples, functionalization of a metal fiber may be effectuated via a heat treatment. In examples, a wick 310 may include metal and polymer materials. In examples, a wick 310 may include polymer fibers coated with a metal. In examples, a wick 310 may include in the fiber and/or as a coating over the fiber a metal such as copper, nickel, titanium, aluminum, or any combination or alloy thereof. In examples, the metal included in the fibers of a wick 310 may be the same as the metal used for a mesh or fibers used for wicks previously described like a mesh wick. In examples, one or more fibers of a fiber wick and/or a metal coating over fibers of fiber wick may extend over at least a portion of a mesh or fibers used for a mesh wick. In examples, a fiber wick may be thermally bonded to the mesh or fiber of another wick. In examples, the metal in fiber wick and/or metal coating over fibers of fiber wick may be used to thermally bond the fiber wick to the mesh or fiber of another wick. In examples, the connection may be made by welding. In examples, the connection may be by thermosonic bonding, laser welding, brazing, or any other suitable thermal process. In examples, the fibers of fiber wick may be bonded over mesh and/or fiber of another wick.

In examples, a thermal system 300 may employ the first glass tube 304 as an evaporation side and the second glass tube 306 as a condensation side. In examples, an electronic device may be equipped with a thermal system 300 and may include a glass tube at a first location where heat is mostly generated, such as for example, proximate to and/or thermally coupled to one or more electronic components. In examples, a glass tube of a thermal system 300 may be provided at a second location of the electronic device where heat is not generated and/or less heat is generated than the first location. In examples, a first end of a glass tube may couple to the memory material coupler 302A and a second end of the glass tube opposite the first end may be coupled to an electronic component of the electronic device. In examples, the electronic device may include a curved portion, a mechanical articulation, and/or hinge including a memory material coupler 302A between a first location and a second location of the electronic device. In examples, memory material coupler 302A of thermal system 300 may be arranged to correspond to a hinge, curved portion, and/or mechanical articulation portion of the electronic device to accommodate the hinge, curved portion, and/or mechanical articulation of the electronic device with minimal to no impedance imposed on the heat spreading functionality.

FIG. 3B illustrates an example thermal system 300 in which a memory material coupler 302B is used to connect two differently sized thermal management components of a thermal system 300. For example, a memory material coupler 302B may be configured to couple a first glass tube 304 have an outer diameter of a first dimension and a second glass tube 306 having an outer diameter of a second dimension different than the first dimension. In examples, the first glass tube and the second glass tube may have an outer diameter ranging between about 0.35 mm to 3 mm. In examples, the first glass tube or the second glass tube may have an inner diameter ranging between about 0.15 mm to 2.8 mm. In examples, the first glass tube or the second glass tube may have a wall thickness of at least 0.1 mm. In some examples, a memory material coupler 302B may be configured to couple a vapor chamber of a first size to a second vapor chamber of a second size different than the first size.

In examples, the memory material coupler 302B may have one or more strain relief features. For instance, in the example of FIG. 3B, the memory material coupler 302B includes ends that taper 314 to a thinner wall thickness which may be more flexible or compliant and thereby reduce an amount of stress imparted by the memory material coupler 302B to the glass tubes. Additionally or alternatively, as shown in FIG. 3C, the memory material coupler 302C may have striations 318 located on one or more mating ends (or receiving ends) of the memory material coupler 302C. In examples, the striations 318 may be configured to help remove strain from the thermal management components when the memory material coupler 302B is bent. Additionally or alternatively, the memory material coupler 302B may include one or more longitudinal slits over a portion of an interface between the memory material coupler 302 and the one or more thermal management components.

FIG. 3C illustrates an example thermal system 300 in which a memory material coupler 302C is used to connect three thermal management components of a thermal system 300. In examples, the memory material coupler 302C may be configured to couple any number of thermal management components, vapor chambers, glass tubes, or heat pipes. For example, the memory material coupler 302C may be configured to couple a first glass tube 304, a second glass tube 306, and a third glass tube 316.

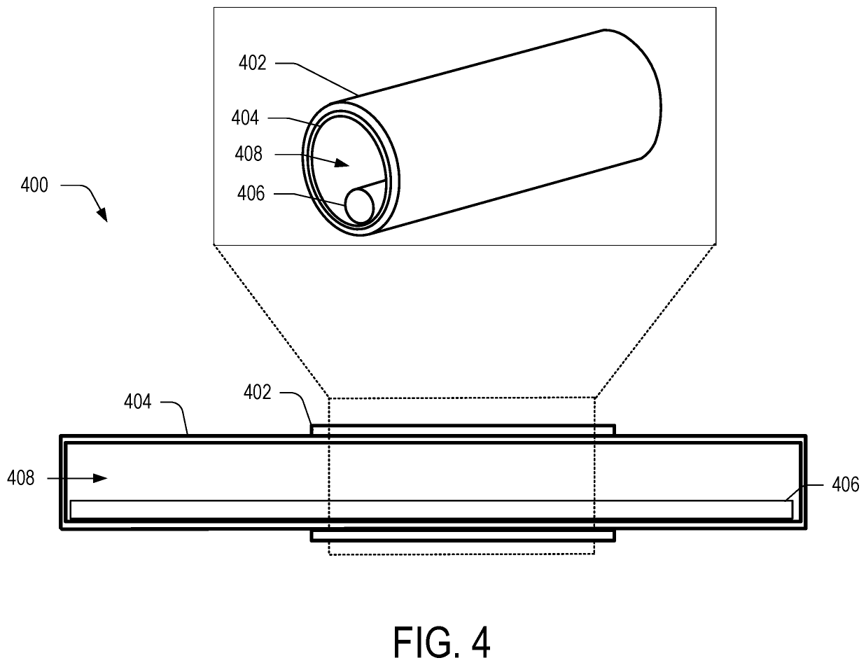

FIG. 4 illustrates an example thermal system 400 including a thermal management component 404 (e.g., a heat pipe) including a memory metal cladding 402 (e.g., a nickel-titanium cladding). In examples, the thermal system 400 may include a single thermal management component or two or more fluidly connected thermal management components. In examples, the thermal management component 404 may include a vapor space 408 including one or more wick(s) 406 and configured to hold and transfer fluid as discussed above.

In examples, the thermal system 400 may be positioned within one or more static curved portions and/or mechanical articulation regions within an electronic device that can pivot, rotate, bend, flex in one or multiple directions, or otherwise translate across a plane. In examples, the memory metal cladding 402 may be configured to provide mechanical articulation provided in an electronic device including a hinge, fold, joint, pivoting element, or other flexible joint and/or bendable member.

In examples, the memory metal cladding 402 may be formed by adding a NiTi cladding layer to one or more sides of the thermal management component 404. In examples, the NiTi cladding layer may be formed by coextrusion, roll bonding, plating, deposition, or other suitable manufacturing techniques. In examples, a thermal management component 404 may include a memory metal cladding 402 layer on one or more sides of the thermal management component 404. In examples, the cladding layer may include NiTi. In examples, the NiTi may include 50% nickel, 51% nickel. In examples, NiTi may be a binary alloy including nickel and titanium. In examples, NiTi may include a ternary alloy that may include nickel, titanium, and a third metal as previously described. In examples, the memory metal cladding 402 of NiTi may be provided over a thermal management component 404 made of copper in order to form a flexible adapter hinge. In examples, thermal properties can be managed by the copper layer while the NiTi can provide the high fatigue strength layer that bears the bending movement and action during use. The NiTi cladding layer has a higher fatigue limit as compared to other materials, such as copper or aluminum. The NiTi increases the number of fold/unfold cycles of the thermal management component and thus increases the service life of the thermal management system. In examples, the NiTi can accommodate between about 250,000 and 500,000 fold/unfold cycles.

In examples, the thermal management component 404 (e.g., heat pipe, vapor chamber, etc.) may be associated with a first fatigue limit and the cladding layer (NiTi cladding layer) may be associated with a second fatigue limit higher than the first fatigue limit. A fatigue limit (or endurance limit) is the stress value below which a number of loading cycles (i.e., fold/unfold cycles) can be applied to a material without causing fatigue failure.

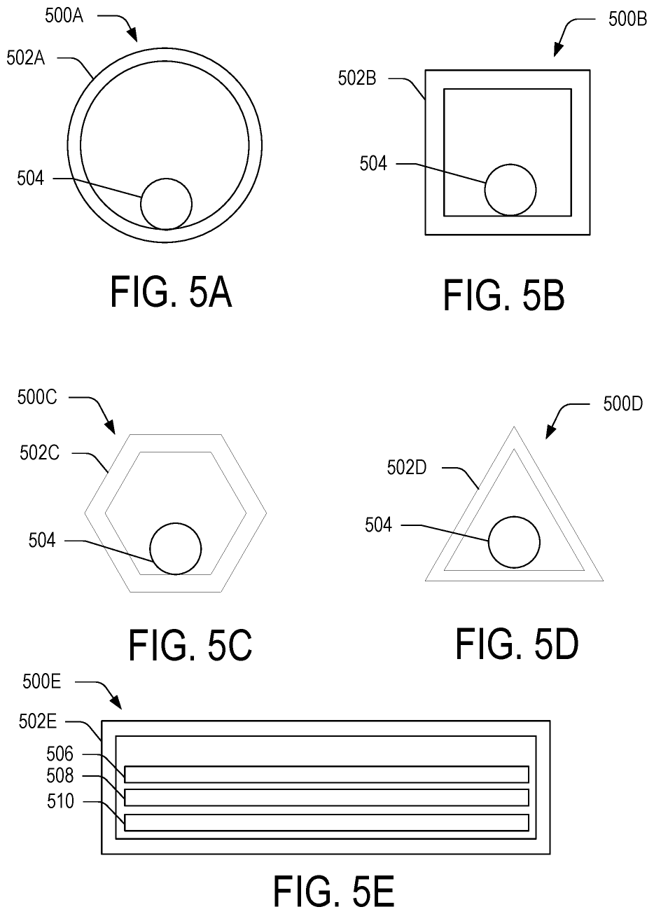

FIGS. 5A-5E illustrate example cross-sectional views of thermal systems 500A-500E including a thermal management component including one or more wick(s). In examples, thermal management component 502A, 502B, 502C, 502D, and/or 502E may be a heat pipe (e.g., a glass tube, a copper tube, etc.), a vapor chamber, or any other thermal management component configured to allow a heat transfer liquid to flow therethrough. In examples, thermal management component 502A, 502B, 502C, 502D, and/or 502E may comprise a metal such as, titanium, nickel, copper, aluminum, magnesium, steel, or any alloys and/or combinations thereof. In some examples, thermal management component 502A, 502B, 502C, 502D, and/or 502E may include high strength polymers (such as polyamideimide (PAI), polyetherimide (PEI), polyetheretherketone (PEEK), polyphenylene sulfide (PPS), Nylon, with or without fiber reinforcement), polyurethan, polypropylene, polyimide, polyethylene terephthalate (PET), composites such as carbon fiber or fiberglass, or any combination thereof.

In examples, thermal management component 502A, 502B, 502C, 502D, and/or 502E may be configured to include a fluid to improve heat transfer and/or heat dissipation. The fluid may be any fluid to transfer heat. In examples, the fluid may be water, deionized water, an aqueous solution such as for example solutions of ethylene glycol and water or propylene glycol and water, an alcohol, or organic fluid such as acetone, dielectric coolants, and perfluorinated carbons solution.

In examples, thermal management component 502A, 502B, 502C, 502D, and/or 502E may be sized and shaped to any desired dimension for a given design architecture. For example, thermal management component 502A may have a cylindrical shape, thermal management component 502B may be a cuboidal shape, thermal management component 502C may have a hexagonal shape, thermal management component 502D may have a triangular shape, thermal management component 502E may have a rectangular shape (e.g., similar to a vapor chamber) etc. Thermal management component(s) 502A, 502B, 502C, 502D, and/or 502E may include one or more wick(s) 504. For example, thermal management components 502A, 502B, 502C, and 502D are depicted as including a single wick 504 and thermal management component 502E is depicted as including a first wick 506, a second wick 508, and a third wick 510. However, any number of wicks may be positioned within thermal management components 502A, 502B, 502C, 502D, and/or 502E.

Although the discussion above sets forth examples of the described techniques and structural features, other architectures may be used to implement the described functionality and are intended to be within the scope of this disclosure. Furthermore, although the subject matter has been described in language specific to structural features and/or methodological acts, it is to be understood that the subject matter defined in the appended claims is not necessarily limited to the specific features or acts described. Rather, the specific features and acts are disclosed as exemplary forms of implementing the claims. For example, the structural features and/or methodological acts may be rearranged and/or combined with each other and/or other structural features and/or methodological acts. In various examples, one or more of the structural features and/or methodological acts may be omitted.

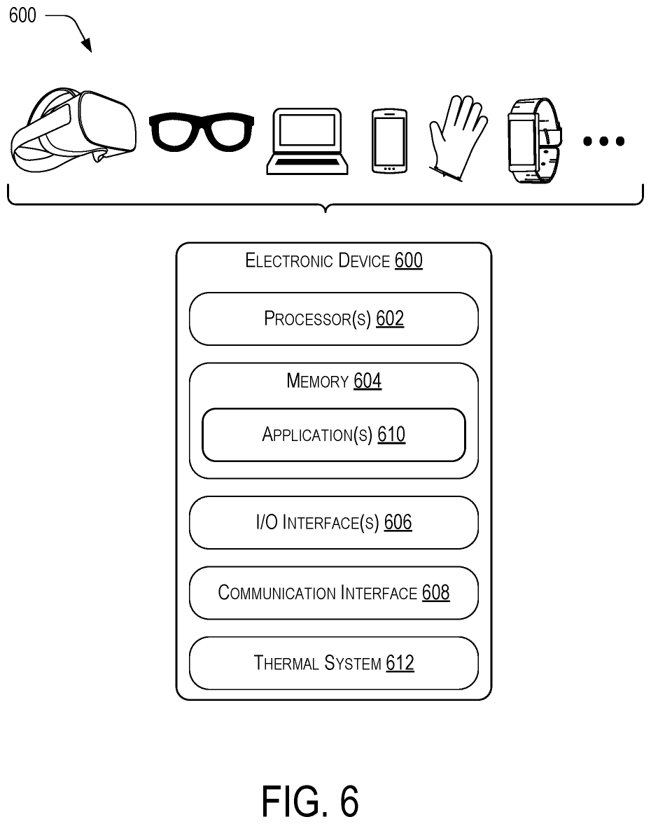

FIG. 6 illustrates an example electronic device 600 usable to implement techniques such as those described herein. The electronic device 600 may be representative of a wearable device such as a watch, a haptic feedback glove, a wristband, a belt, an armband, a head-mounted device such as an extended reality headset or glasses, a portable device such as a laptop computer, a mobile device such as a tablet or mobile phone, a rollable or foldable device (e.g., a foldable phone or e-reader) or any other electronic device such as those described throughout this application.

As shown, the electronic device 600 may include one or more electronic components such as processors 602, memory 604, input/output interfaces 606 (or “I/O interfaces 606”), and communication interfaces 608, which may be communicatively coupled to one another by way of a communication infrastructure (e.g., a bus, traces, wires, etc.). While the electronic device 600 is shown in FIG. 1 having a particular configuration, the components illustrated in FIG. 1 are not intended to be limiting. The various components can be rearranged, combined, and/or omitted depending on the requirements for a particular application or function. Additional or alternative components may be used in other examples.

In some examples, the processor(s) 602 may include hardware for executing instructions, such as those making up a computer program or application. For example, to execute instructions, the processor(s) 602 may retrieve (or fetch) the instructions from an internal register, an internal cache, the memory 604, or other computer-readable media, and decode and execute them. By way of example and not limitation, the processor(s) 602 may comprise one or more central processing units (CPUs), graphics processing units (GPUs), holographic processing units, microprocessors, microcontrollers, integrated circuits, programmable gate arrays, or other hardware components usable to execute instructions.

The memory 604 is an example of computer-readable media and is communicatively coupled to the processor(s) 602 for storing data, metadata, and programs for execution by the processor(s) 602. In some examples, the memory 604 may constitute non-transitory computer-readable media such as one or more of volatile and non-volatile memories, such as Random-Access Memory (“RAM”), Read-Only Memory (“ROM”), a solid-state disk (“SSD”), Flash, Phase Change Memory (“PCM”), or other types of data storage. The memory 604 may include multiple instances of memory and may include internal and/or distributed memory. The memory 604 may include removable and/or non-removable storage. The memory 604 may additionally or alternatively include one or more hard disk drives (HDDs), flash memory, Universal Serial Bus (USB) drives, or a combination these or other storage devices.

As shown, the electronic device 600 includes one or more I/O interfaces 606, which are provided to allow a user to provide input to (such as touch inputs, gesture inputs, keystrokes, voice inputs, etc.), receive output from, and otherwise transfer data to and from the electronic device 600. Depending on the particular configuration and function of the electronic device 600, the I/O interface(s) 606 may include one or more input interfaces such as keyboards or keypads, mice, styluses, touch screens, cameras, microphones, accelerometers, gyroscopes, inertial measurement units, optical scanners, other sensors, controllers (e.g., handheld controllers, remote controls, gaming controllers, etc.), network interfaces, modems, other known I/O devices or a combination of such I/O interface(s) 606. Touch screens, when included, may be activated with a stylus, finger, thumb, or other object. The I/O interface(s) 606 may also include one or more output interfaces for presenting output to a user, including, but not limited to, a graphics engine, a display (e.g., a display screen, projector, holographic display, etc.), one or more output drivers (e.g., display drivers), one or more audio speakers, and one or more audio drivers. In certain examples, I/O interface(s) 606 are configured to provide graphical data to a display for presentation to a user. The graphical data may be representative of one or more graphical user interfaces and/or any other graphical content as may serve a particular implementation. By way of example, the I/O interface(s) 606 may include or be included in a wearable device, such as a head-mounted display (e.g., headset, glasses, helmet, visor, etc.), a suit, gloves, a watch, or any combination of these, a handheld electronic device (e.g., tablet, phone, handheld gaming device, etc.), a portable electronic device (e.g., laptop), or a stationary electronic device (e.g., desktop computer, television, set top box, a vehicle electronic device). In some examples, the I/O interface(s) 606 may be configured to provide an extended reality environment or other computer-generated environment. As used herein, an extended reality environment includes an at least partially computer-generated environment, such as virtual reality, augmented reality, and/or mixed reality, and extended reality devices or headsets are devices configured to provide all or a portion of an extended reality environment.

The electronic device 600 may also include one or more communication interface(s) 608. The communication interface(s) 608 can include hardware, software, or both. In examples, communication interface(s) 608 may provide one or more interfaces for physical and/or logical communication (such as, for example, packet-based communication) between the electronic device 600 and one or more other electronic devices or one or more networks. As an example, and not by way of limitation, the communication interface(s) 608 may include a network interface controller (NIC) or network adapter for communicating with an Ethernet or other wire-based network and/or a wireless NIC (WNIC) or wireless adapter for communicating with a wireless network, such as a WI-FI adapter. In examples, communication interface(s) 608 can additionally include a bus, which can include hardware (e.g., wires, traces, radios, etc.), software, or both that communicatively couple components of electronic device 600 to each other. In examples, the electronic device 600 may include additional or alternative components that are not shown, such as, but not limited to, a power supply (e.g., batteries, capacitors, etc.), a housing or other enclosure to at least partially house or enclose any or all of the components.

The memory 604 may store one or more applications 610, which may include, among other things, an operating system (OS), productivity applications (e.g., word processing applications), communication applications (e.g., email, messaging, social networking applications, etc.), games, or the like. The application(s) 610 may be implemented as one or more stand-alone applications, as one or more modules of an application, as one or more plug-ins, as one or more library functions application programming interfaces (APIs) that may be called by other applications, and/or as a cloud-computing model. The application(s) 610 can include local applications configured to be executed locally on the electronic device, one or more web-based applications hosted on a remote server, and/or as one or more mobile device applications or “apps.”

In examples, the electronic device 600 may also include a thermal system 612 as described herein, to which the other electronic components such as the processor(s) 602, memory 604, I/O interface(s) 606, and/or communication interface(s) 608 can be thermally coupled. In examples, the thermal system 612 may be thermally conductive and configured to spread heat generated by the one or more other components. The thermal system 612 can be made of a relatively light weight, rigid material such as any of those described herein, and may be configured to exhibit manufacturing tolerances suitable for mounting precision optical components (e.g., lenses, display screens, mirrors, gratings, optical fibers, light pipes, etc.).

In examples, the electronic device 600 may include one or more static curved portions, hinges, and/or mechanical articulation that pivot, rotate, bend, flex, or otherwise translate across a plane. In examples, a coupler (e.g., a memory material coupler) may be configured to provide mechanical articulation provided in an electronic device including a hinge, fold, joint, pivoting element, or other flexible joint and/or flexible adapter hinge. In examples, a thermal system 612 may extend through at least a portion of a static curved portion or a mechanical articulation such as one provided by a coupler. In examples, a thermal system 612 may extend from a first region of the electronic device 600 to a second region of the electronic device 600, wherein a static curved portion or a mechanical articulation is located between the first region and the second region of the electronic device 600. In examples, the thermal system 612 extends from a first elongated and/or planar portion of electronic device 600 across and/or through a static curved portion or coupler that provides a mechanical articulation and reach a second elongated and/or planar portion of the electronic device 600. In examples, the portion of a thermal system 612 that extends through and/or across a static curved portion or mechanical articulation may include at least a portion of a memory material coupler.

For example, an example electronic device 600 may be as an extended reality headset or glasses. The electronic device may include a first elongated and/or planar portion, such as a face front portion, and a second elongated and/or planar portion, such as a temple arm or side portion, with a static curved portion or mechanical articulation such as a hinge or fold between the first elongated and/or planar portion and the second elongated and/or planar portion. In examples, a thermal system 612 may be provided to extend from first portion to second portion and across or through a static curved portion or mechanical articulation or coupler. In examples, the electronic device may include one or more of the previously discussed components (e.g., processor(s) 602, memory 604, I/O interface(s) 606, and/or communication interface(s) 608) at least at or near the first portion. In examples, the one or more components may be thermally coupled at least to a portion of the thermal system 612 that extends across the first portion. As the electronic device is used, heat generated from the one or more components in the first portion may be transferred to the portion of the thermal system 612 located in the first portion. In examples, thermal system 612 may be configured to transfer or spread the heat from the one or more components to a second portion of the electronic device. In examples, heat may be transferred within thermal system 612 via capillary action and/or thermal conduction from an evaporator region to a condenser region, from a first heat pipe or tube to a second heat pipe or tube, from a first glass tube to a second glass tube, or any combination thereof. In examples, the heat transferred within thermal system 612 may transfer across one or more memory material couplers. In examples, a memory material coupler may be located at an adiabatic region of the thermal system 612.

In examples, a thermal system may include one or more thermal management components and one or more memory material couplers. In examples, the thermal system may include a single thermal management component or two or more fluidly connected thermal management components. In examples, a thermal management system may include a memory material coupler (e.g., a nickel titanium coupler). In examples, a memory material coupler of the thermal system may be an integral part of a thermal management component or may be connected to a thermal management component. In examples, a memory material coupler may be provided between two thermal management components (e.g., between two glass pipes). In examples, a memory material coupler may be configured to accommodate axial, radial, lateral, and/or angular displacement. In examples, a hollow memory material coupler may have an internal diameter or internal width similar to that of one or more thermal management components it connects. In examples, a hollow memory material coupler may have an internal diameter or internal width that is the same size or larger than as at least a thermal management component of which it is part or to which it is connected. For purposes of this disclosure, an internal width is shortest distance between two opposite sides of an internal surface of a memory material coupler when the memory material coupler is not in a bent position. In examples, the memory material coupler may have a length ranging from about 13 mm (about 0.5 inch) to about 80 mm (about 3 inches). In some examples, the memory material coupler may be long enough to extend across a hinge or articulation area of an electronic device, such that only the memory material coupler is subjected to mechanical articulation and not the thermal management components coupled to the memory material coupler. To accomplish this, in some examples, the memory material coupler may be fixed (e.g., welded, brazed, adhered, press fit, clamped, fastened, etc.) at one or both ends to the two articulating portions of the housing. For instance, a first end of the memory material coupler may be fixed to a glasses frame and a second end of the memory material coupler may be fixed to a temple arm such that as the temple arm is pivoted with respect to the glasses frame, the memory material coupler bends or flexes, but the thermal management components coupled thereto remain static (i.e., are not subject to bending or stresses). In examples, forces may be localized at a midpoint of the memory material coupler so that no forces are imparted on the two thermal management components coupled to the memory material coupler.

In examples, a thermal management component associated with the thermal system may include a substantially rigid, flexible, semi-flexible, or light weight structural element or material. A thermal management component can be sized and shaped to any desired dimensions for a given design architecture. In examples, a thermal management component may include an outer shell. In examples, an outer shell to a thermal management component may include a thermally conductive material. In examples, an outer shell of a thermal management component may include a metal such as, titanium, copper, aluminum, magnesium, steel, or any alloys, and/or combinations thereof. In examples, the copper may be oxygen free copper (OFC). In examples, an outer shell of thermal management component may include high strength polymers (such as polyamideimide (PAI), polyetherimide (PEI), polyetheretherketone (PEEK), polyphenylene sulfide (PPS), Nylon, with or without fiber reinforcement), polyurethane, polypropylene, polyimide, polyethylene terephthalate (PET), composites such as carbon fiber or fiberglass, glass or any combination thereof. Other materials may also be used.

In examples, a thermal management component associated with the thermal system may include a fluid to improve heat transfer and/or heat dissipation as described with respect to thermal management component herein. The fluid may be any suitable fluid to transfer heat. In examples, the fluid may be dihydrogen monoxide (i.e., water), deionized water, an aqueous solution such as for example solutions of ethylene glycol and water or propylene glycol and water, an alcohol, or an organic fluid such as for example acetone, dielectric coolants, and perfluorinated carbons solution. Other fluids may also be implemented.

In examples, a thermal management component, such as a heat pipe, vapor chamber, or glass pipe, may include an evaporation or “hot” side where heat is transferred from an electronic component to the thermal management component, and a condensation or “cold” side where heat is spread from the thermal management component. In examples, extending between the evaporation side and condensation side, a thermal management component may include an adiabatic region. In examples, an adiabatic region may include a region where the heat management component transitions from the evaporation side to the condensation side.

In examples, one or more electronic components (e.g. processors, memory, I/O device(s), and/or communication connection(s)) may be thermally coupled to at least a portion of the heat management component. In examples, one or more electronic components may be connected to an evaporator side of thermal management component, to a condensation side of thermal management component, to an adiabatic region of thermal management component, or any combination thereof.

What is claimed is:

1. An electronic device comprising:
a first thermal management component;
a second thermal management component;
a flexible region configured to bend in a first direction;
a memory material coupler disposed within the flexible region of the electronic device and interposed between a mating end of the first thermal management component and a mating end of the second thermal management component and configured to provide mechanical articulation of the first thermal management component relative to the second thermal management component; and
a wick configured to extend from the first thermal management component, through the memory material coupler, to the second thermal management component.

2. The electronic device of claim 1, wherein
the first thermal management component comprises a first vapor chamber and the second thermal management component comprises a second vapor chamber, and
the flexible region is configured to bend in the first direction and a second direction perpendicular to the first direction.

3. The electronic device of claim 1, wherein the memory material coupler is a first memory material coupler, the electronic device further comprising:
a third thermal management component; and
a second memory material coupler disposed within the flexible region of the electronic device and interposed between the third thermal management component and the second thermal management component and configured to provide mechanical articulation of the third thermal management component relative to the second thermal management component.

4. The electronic device of claim 1, wherein the first thermal management component comprises a first glass tube and the second thermal management component comprises a second glass tube.

5. The electronic device of claim 4, wherein the memory material coupler has a smaller inner diameter relative to an outer diameter of the first glass tube and an outer diameter of the second glass tube such that a hermetic seal is formed between the memory material coupler and the first glass tube and the second glass tube.

6. The electronic device of claim 4, wherein
a polyimide coating extends over at least a portion of the first glass tube and a portion of the second glass tube, and
the memory material coupler is positioned about 1 mm away from the polyimide coating extending over the portion of the first glass tube and about 1 mm away from the polyimide coating extending over the portion of the second glass tube.

7. The electronic device of claim 1, wherein the wick comprises:
a first portion comprising a first copper mesh of a first type; and
a second portion comprising a second copper mesh of a second type different than the first type, the first portion and the second portion joined via a mesh junction.

8. The electronic device of claim 1, wherein the wick is a first wick positioned within the first thermal management component, the electronic device further comprising:
a second wick positioned within the second thermal management component, wherein the first wick and the second wick are coupled via a wick memory metal coupler configured to extend across an adiabatic region.

9. The electronic device of claim 1, wherein the memory material coupler is coupled to a housing of the electronic device.

10. The electronic device of claim 1, wherein
the electronic device comprises a portion of a frame of a head-mounted device and a temple arm coupled to the frame of the head-mounted device via a hinge,
the first thermal management component is disposed in the frame of the head-mounted device and the second thermal management component is disposed in the temple arm, and
the memory material coupler is coupled to the frame of the head-mounted device or the temple arm of the head-mounted device in order to minimize stresses imparted to the first thermal management component and the second thermal management component.

11. The electronic device of claim 1, wherein
the electronic device comprises a portion of a frame of a head-mounted device and a strap coupled to the frame of the head-mounted device via an articulation region, and
the first thermal management component is disposed in the frame of the head-mounted device and the second thermal management component is disposed in the strap.

12. The electronic device of claim 1, wherein the electronic device is a flexible wearable device.

13. The electronic device of claim 1, further comprising:
a third thermal management component;
a fourth thermal management component; and
wherein the memory material coupler is interposed between the first thermal management component, the second thermal management component, the third thermal management component, and the fourth thermal management component.

14. A bendable thermal system comprising:
a first thermal management component;
a second thermal management component; and
a memory material coupler disposed within a flexible region of an electronic device, the memory material coupler interposed between a first mating end of the first thermal management component and a second mating end of the second thermal management component such that the memory material coupler enables the bendable thermal system to bend in multiple directions across a plane.

15. The bendable thermal system of claim 14, further comprising:
a first wick structure of a first type positioned within the first thermal management component; and
a second wick structure of a second type different than the first type positioned within the second thermal management component.

16. The bendable thermal system of claim 15, wherein the first wick structure and the second wick structure are coupled via a wick memory material coupler.

17. The bendable thermal system of claim 14, wherein a first end of the memory material coupler includes a plurality of striations over a portion of an interface between the first thermal management component and the first end of the memory material coupler.

18. The bendable thermal system of claim 14, further comprising:
a third thermal management component, wherein the memory material coupler is coupled to a third mating end of the third thermal management component.

19. A method comprising:
forming a nickel-titanium coupler at least in part by:
drawing a nickel-titanium alloy at a temperature in a range of about 800 to 1000 degrees Celsius;
drawing and inter-annealing the nickel-titanium alloy at a temperature in the range of 500 to 600 degrees Celsius;
annealing the nickel-titanium alloy at a temperature in the range of 300 to 550 degrees Celsius;
providing a first thermal management component;
providing a second thermal management component;
coupling, while the nickel-titanium coupler is at a temperature of at least about 500 degrees Celsius, the nickel-titanium coupler to a mating end of the first thermal management component and a mating end of the second thermal management component; and
cooling the nickel-titanium coupler such that the nickel-titanium coupler contracts and forms a compression fit between the nickel-titanium coupler, the first thermal management component, and the second thermal management component.

20. The method of claim 19, wherein the first thermal management component comprises a first glass tube and the second thermal management component comprises a second glass tube.
